(19) United States
(12) Patent Application Publication
(10) Pub. No.: US 2007/0246772 A1
(43) Pub. Date: Oct. 25, 2007

(54) MOSFET power package

(76) Inventors: James Lee, Taipei (TW); Tommy Ro, Taipei (TW); Alice Gong, Pudong (CN)

Correspondence Address: FORTUNE LAW GROUP LLP, 100 CENTURY CENTER COURT, SUITE 315, SAN JOSE, CA, 95112, US

(21) Appl. No.: 11/396,407

(22) Filed: Mar. 31, 2006

(51) Int. Cl. H01L 29/76; H01L 23/495; H01L 23/48

(52) U.S. Cl. 257/341; 257/690; 257/676

(57) ABSTRACT

A power MOSFET package is disclosed. The power MOSFET package includes a leadframe having first and second die pads insulated one from the other, the first die pad being coupled to a first drain lead and the second die pad being coupled to a second drain lead. A first MOSFET device has a drain contact coupled-to the first die pad, a gate contact coupled to a first gate lead, and a source contact coupled to the second die pad. A second MOSFET device has a drain contact coupled to the second die pad, a gate contact coupled to a second gate lead, and a source contact coupled to a source lead. An encapsulant substantially encapsulates the leadframe, the first and second MOSFET devices and portions of the first and second gate leads, the first and second drain leads, and the source lead.

### BACKGROUND OF THE INVENTION

The present invention generally relates to a MOSFET power package and more particularly to a 5-lead TO-252 power MOSFET package for use in implementing a synchronous buck converter.

Synchronous buck converters provide a smaller size and higher efficiency in portable battery-operated applications including notebook computer applications. A conventional synchronous buck converter is shown in FIG. 2 and generally designated 200. A first N-channel enhancement MOSFET 210 is coupled to a second N-channel enhancement MOSFET 220 in a conventional manner wherein the source of the first MOSFET 210 is connected to the drain of the second MOSFET 220.

While it is known to provide two power MOSFETs in a TO-252 package in a common drain configuration as shown in FIG. 1, the synchronous buck converter 200 is conventionally implemented with discreet components and requires a large amount of printed circuit board (PCB) space. As shown in FIG. 3, a high side MOSFET 300 and a low side MOSFET 310 are surface mounted to the PCB and coupled to other circuit components including an inductor 333.

As electronic devices are miniaturized, a need exists for smaller package sizes and optimized device lead layout to save PCB space. There is therefore a need in the art for a power MOSFET package for use in implementing a synchronous buck converter that optimizes device lead layout and saves PCB space. There is also a need for a 5-lead TO-252 power MOSFET package for use in implementing a synchronous buck converter.

### SUMMARY OF THE INVENTION

The present invention provides a 5-lead TO-252 power MOSFET package for implementing a synchronous buck converter that reduces package size and optimizes lead layout to save PCB space.

In accordance with one aspect of the invention, a power MOSFET package includes a leadframe having first and second die pads insulated one from the other, the first die pad being coupled to a first drain lead and the second die pad being coupled to a second drain lead. A first MOSFET device has a drain contact coupled to the first die pad, a gate contact coupled to a first gate lead, and a source contact coupled to the second die pad. A second MOSFET device has a drain contact coupled to the second die pad, a gate contact coupled to a second gate lead, and a source contact coupled to a source lead. An encapsulant substantially encapsulates the leadframe, the first and second MOSFET devices and portions of the first and second gate leads, the first and second drain leads, and the source lead.

In accordance with another aspect of the invention, a power MOSFET package for providing power and synchronous switching to a synchronous buck converter circuit includes a leadframe having first and second die pads insulated one from the other, the first die pad being coupled to a first drain lead and the second die pad being coupled to a second drain lead. A first MOSFET device has a drain contact coupled to the first die pad, a gate contact coupled to a first gate lead, and a source contact coupled to the second die pad. A second MOSFET device has a drain contact coupled to the second die pad, a gate contact coupled to a second gate lead, and a source contact coupled to a source lead. An encapsulant substantially encapsulating the leadframe, the first and second MOSFET devices and portions of the first and second gate leads, the first and second drain leads, and the source lead.

There has been outlined, rather broadly, the more important features of the invention in order that the detailed description thereof that follows may be better understood, and in order that the present contribution to the art may be better appreciated. There are, of course, additional features of the invention that will be described below and which will form the subject matter of the claims appended herein.

In this respect, before explaining at least one embodiment of the invention in detail, it is to be understood that the invention is not limited in its application to the details of the method set forth in the following description or illustrated in the drawings. The invention is capable of other embodiments and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

These and other features, aspects and advantages of the present invention will become better understood with reference to the following drawings, description and claims.

### BRIEF DESCRIPTION OF THE DRAWINGS

FIG. 1 is a schematic representation of a prior art TO-252 package leadframe;

FIG. 1A is a top view of a TO-252 package of the prior art;

FIG. 2 is a circuit diagram of a synchronous buck converter;

FIG. 3 is a PCB layout of a prior art synchronous buck converter;

FIG. 4 is a PCB layout of a synchronous buck converter in accordance with the invention;

FIG. 5 is a schematic representation of a TO-252 package leadframe in accordance with the invention; and

FIG. 5A is a top view of a TO-252 package in accordance with the invention.

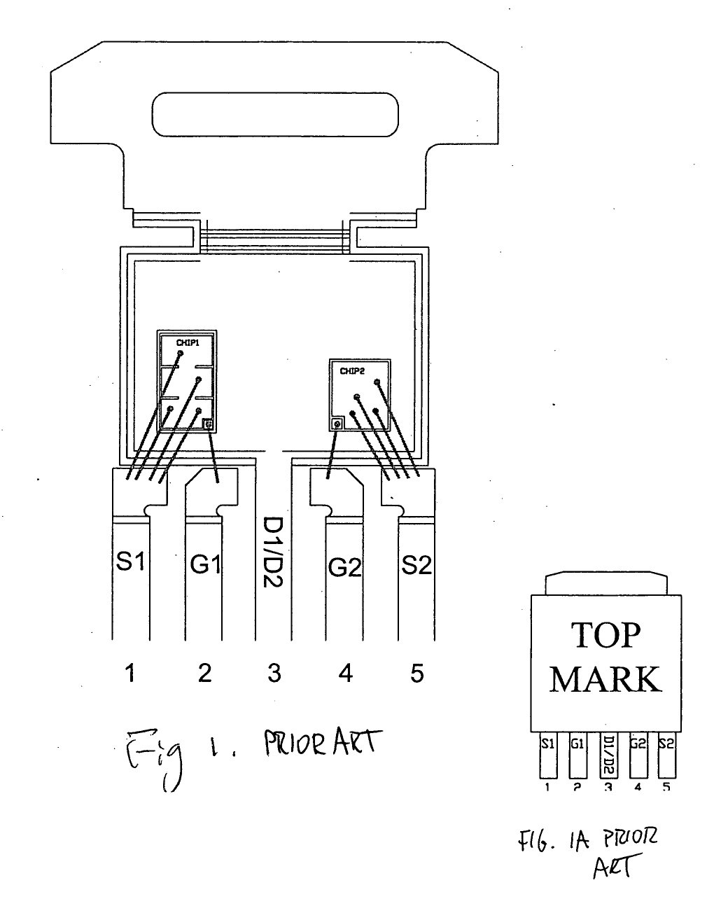

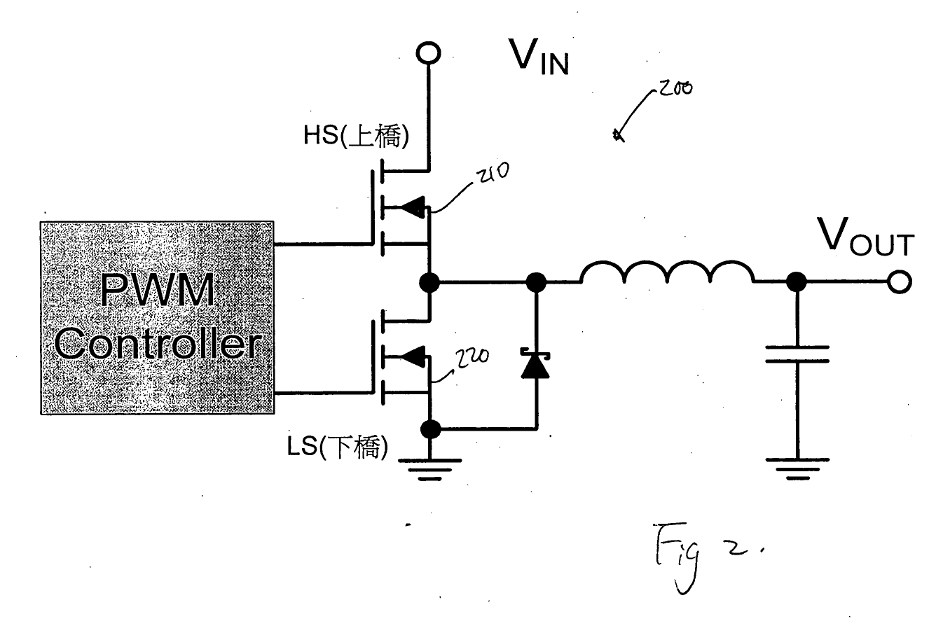

### DETAILED DESCRIPTION OF THE INVENTION

The present invention provides a TO-252 power MOSFET package for use in implementing a synchronous buck converter. With reference to FIG. 5, a TO-252 package leadframe 500 includes a pair of drain pads 510 and 520 having disposed thereon MOSFETs 515 and 525 respectively. Drain pads 510 and 520 are insulated from each other after a connecting portion 505 is trimmed off along dashed line A-A at the end of the packaging process. MOSFETs 515 and 520 are preferably soldered to drain pads 510 and 520 respectively or, alternatively, attached using conductive epoxy.

Wire bonding 530 connects the source of MOSFET 515 to the drain pad 520. A gate of MOSFET 515 is wire bonded to gate lead G1 by wire bond 517, a gate of MOSFET 525 is wire bonded to gate lead G2 by wire bond 527, and a source of MOSFET 525 is wire bonded to source lead S2 by wire bonding 540. A lead D1 is coupled to drain pad 510 while a lead D2/S1 is coupled to drain pad 520.

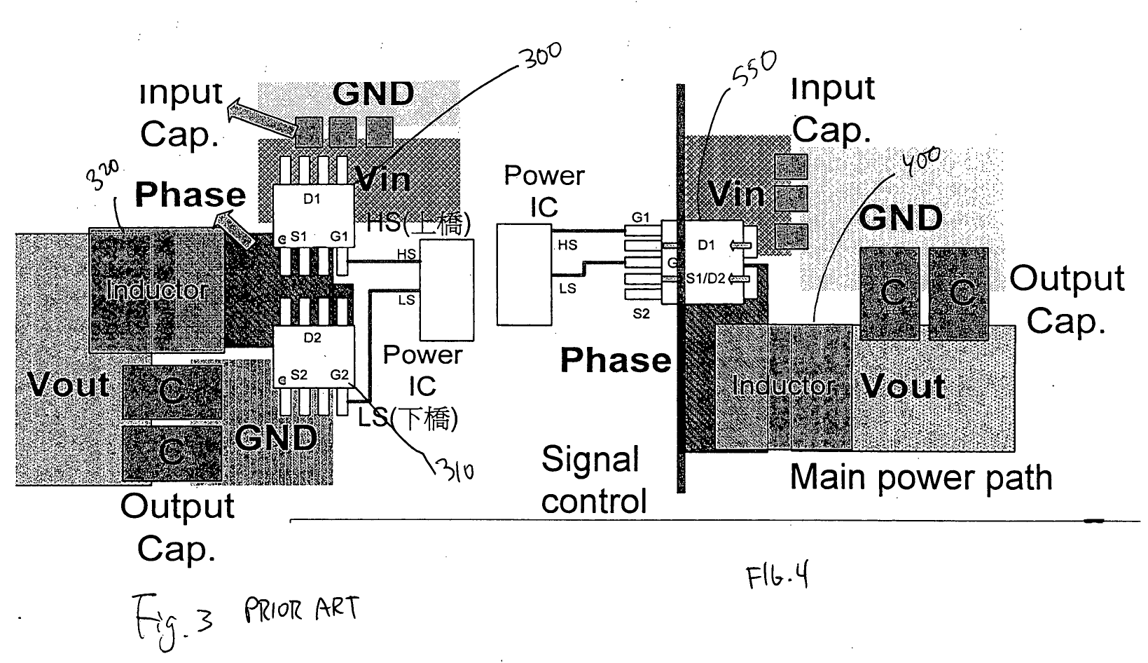

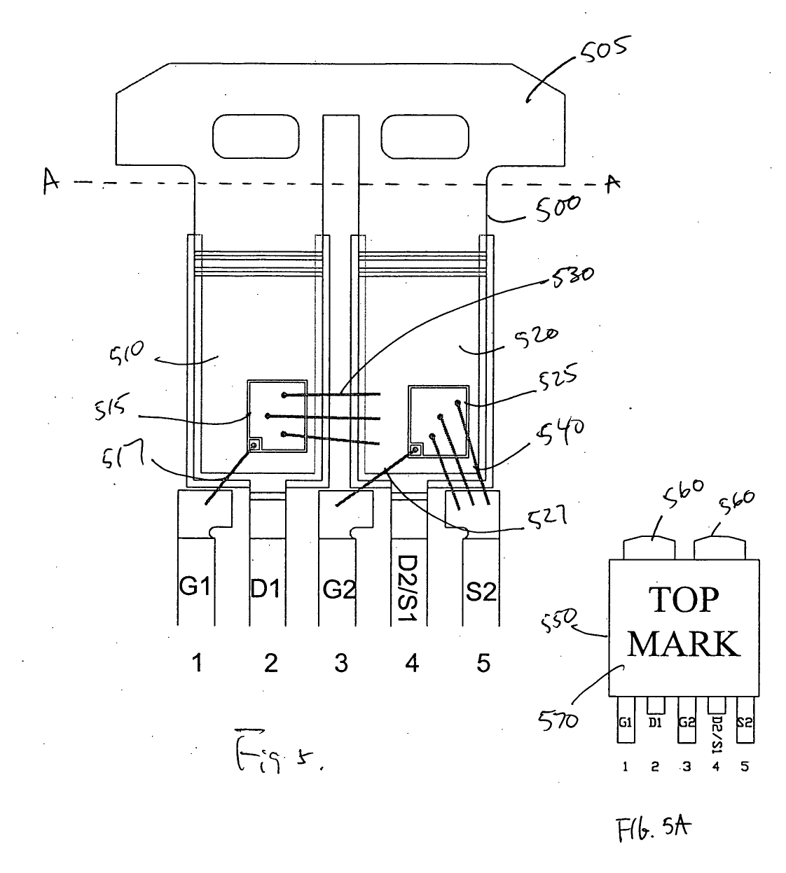

A TO-252 package 550 in accordance with the invention is shown in FIG. 5A and includes headers 560 and a plastic molding 570. In use, and as shown in FIG. 4, the package 550 may be used to implement a synchronous buck converter 400. The synchronous buck converter 400 using the package 550 uses less PCB space in comparison to the conventional PCB layout shown in FIG. 3. The package 550 advantageously provides an optimized lead layout. Including a 5-lead TO-252 package configuration.

It should be understood, of course, that the foregoing relates to preferred embodiments of the invention and that modifications may be made without departing from the spirit and scope of the invention as set forth in the following claims.

We claim:

1. A power MOSFET package comprising:
a leadframe having first and second die pads insulated one from the other, the first die pad being coupled to a first drain lead and the second die pad being coupled to a second drain lead;
a first MOSFET device having a drain contact coupled to the first die pad, a gate contact coupled to a first gate lead, and a source contact coupled to the second die pad;
a second MOSFET device having a drain contact coupled to the second die pad, a gate contact coupled to a second gate lead, and a source contact coupled to a source lead; and
an encapsulant substantially encapsulating the leadframe, the first and second MOSFET devices and portions of the first and second gate leads, the first and second drain leads, and the source lead.

2. The power MOSFET package of claim 1, wherein the package is a TO-252 package.

3. The power MOSFET package of claim 1, wherein the package is operable to provide power and synchronous switching to a synchronous buck converter circuit.

4. A power MOSFET package for providing power and synchronous switching to a synchronous buck converter circuit comprising:
a leadframe having first and second die pads insulated one from the other, the first die pad being coupled to a first drain lead and the second die pad being coupled to a second drain lead;
a first MOSFET device having a drain contact coupled to the first die pad, a gate contact coupled to a first gate lead, and a source contact coupled to the second die pad;
a second MOSFET device having a drain contact coupled to the second die pad, a gate contact coupled to a second gate lead, and a source contact coupled to a source lead; and
an encapsulant substantially encapsulating the leadframe, the first and second MOSFET devices and portions of the first and second gate leads, the first and second drain leads, and the source lead.

5. The power MOSFET package of claim 4, wherein the package is a TO-252 package.
